(19) United States
(12) Patent Application Publication
(10) Pub. No.: US 2007/0147000 A1
(43) Pub. Date: Jun. 28, 2007

(54) MOTHERBOARD ASSEMBLY

(75) Inventor: SZU-WEI KUO, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,546

(22) Filed: Aug. 18, 2006

(30) Foreign Application Priority Data
Dec. 23, 2005 (CN) 200520121199.X

(51) Int. Cl. H05K 7/20

(52) U.S. Cl. 361/704

(57) ABSTRACT

An exemplary motherboard assembly includes a printed circuit board (PCB), and a heat sink. The PCB includes an electronic component mounted thereto. The heat sink includes a main body, and a shielding member mounted to a bottom of the main body. The shielding member defines an opening therein for accommodating the electronic component. The shielding member is sandwiched between the bottom of the main body and the PCB. The heat sink can remove heat generated by the electronic component and shield EMI generated by the electronic component, as well.

### FIELD OF THE INVENTION

The present invention relates to motherboards, and particularly to a motherboard having a heat sink preventing electromagnetic interference (EMI) generated by electronic components thereof.

### DESCRIPTION OF RELATED ART

Heat sinks are usually used to remove heat from electronic heat-generating components, such as central processing units (CPUs) etc., to ensure stable operation of the components. A typical heat sink includes a base attached to a heat-generating component to absorb heat therefrom, and a plurality of parallel planar fins extending up from the base. The fins are used for dissipating the heat. However, typical heat sinks only remove heat from the electronic heat-generating components without providing EMI shielding.

Therefore, an improved motherboard assembly with a heat sink which overcomes the above-mentioned problems is desired.

### SUMMARY OF THE INVENTION

An exemplary motherboard assembly includes a printed circuit board (PCB), and a heat sink. The PCB includes an electronic component mounted thereto. The heat sink includes a main body, and a shielding member mounted to a bottom of the main body. The shielding member defines an opening therein for accommodating the electronic component. The shielding member is sandwiched between the bottom of the main body and the PCB.

Other advantages and novel features will become more apparent from the following detailed description when taken in conjunction with the accompanying drawings, in which:

### BRIEF DESCRIPTION OF THE DRAWINGS

FIG. 1 is an exploded, isometric view of one embodiment of a motherboard in accordance with the present invention, the motherboard includes a heat sink;

FIG. 2 is an isometric view of the heat sink of FIG. 1;

FIG. 3 is a cross-sectional view taken along line 11-11 of FIG. 2; and

FIG. 4 is an assembled view of FIG. 1.

### DETAILED DESCRIPTION OF THE INVENTION

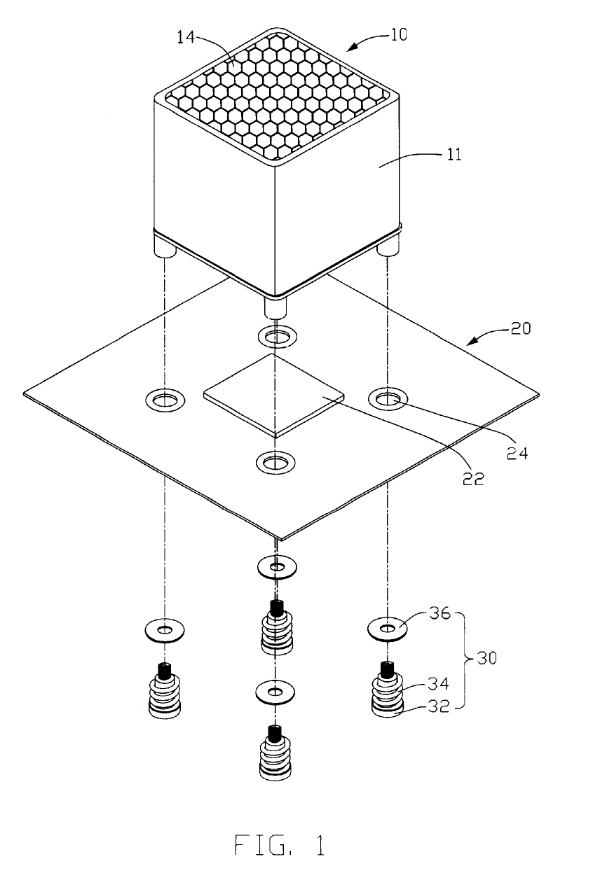

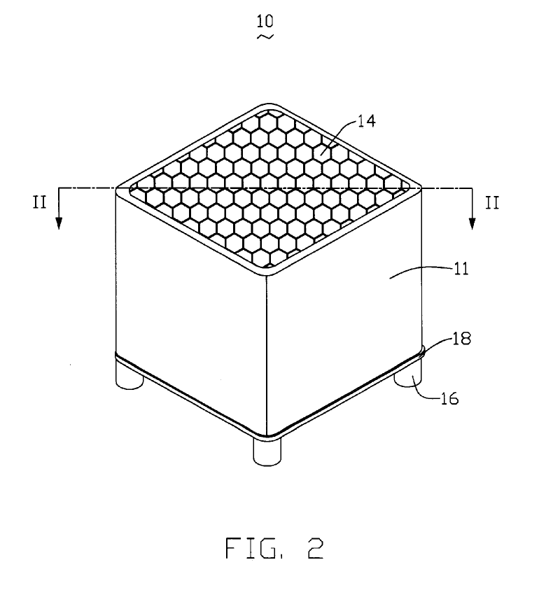

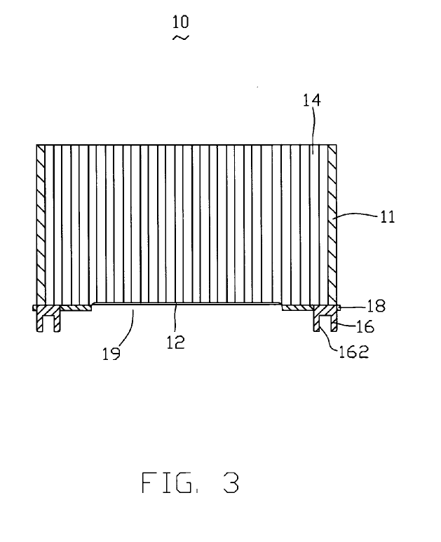

Referring to FIGS. 1-3, a motherboard assembly in accordance with a preferred embodiment of the present invention includes a printed circuit board (PCB) 20, a heat sink 1 0, and a plurality of fasteners 30.

The PCB 20 includes an electronic component, such as a CPU 22, mounted thereto. Four through-holes 24 are defined in the PCB 20 surrounding the CPU 22.

The heat sink 10 includes a square column shaped main body 11, a shielding member 18 mounted to a bottom of the main body 11 with adhesive such as glue, and four posts 16 extending down from four corners of the bottom of the main body 11 respectively. The posts 16 are in alignment with the corresponding through-holes 24 of the PCB 20 for mounting the heat sink 10 to the PCB 20.

The main body 11 defines a plurality of blind holes 14 therein, and a recess 12 in a middle portion of the bottom of the main body 11, for receiving the CPU 22. Each of the blind holes 14 is open at a top of the main body 11 and close at a bottom of the main body 11. An array of the blind holes 14 is in the form of a honeycomb or other desired configuration. Each of the blind holes 14 has a maximum width less than one-hundredth of a wavelength of electromagnetic waves generated by the CPU 22. Thus, the blind holes 14 have a capability of reducing EMI generated by the CPU 22. Each post 16 defines a screw hole 162 in a bottom thereof.

Each fastener 30 includes a screw 32, a coil spring 34, and a gasket 36.

The shielding member 18 is made of electric sponge for shielding electromagnetic waves. The shielding member 18 defines an opening 19 in a middle portion thereof corresponding to the CPU 22, and four through-holes corresponding to the posts 16.

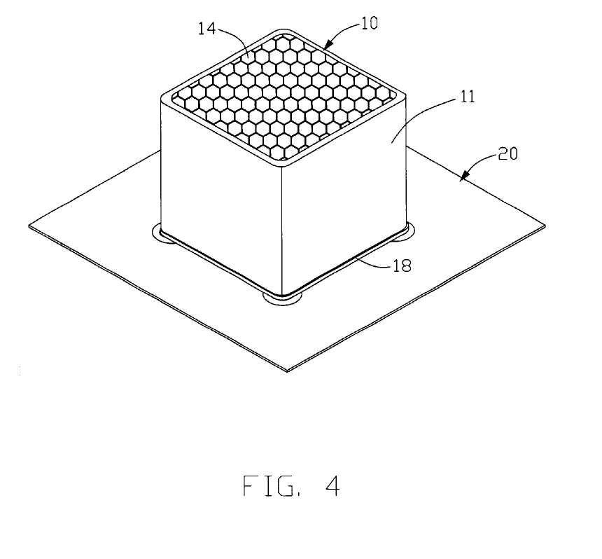

Referring also to FIG. 4, in assembly, the posts 16 of the main body 11 are inserted through the through-holes of the shielding member 18, to mount the shielding member 18 to the bottom of the main body 11. The posts 16 are inserted through the corresponding through-holes 24 of the PCB 20. Each screw 32 fits about a corresponding coil spring 34 and a corresponding gasket 36, and then engages in the screw hole 162 of a corresponding post 16. Thus, the heat sink 10 is mounted to the PCB 20. The CPU 22 is received in the recess 12 of the heat sink 10 and the opening 19 of the shielding member 18. The shielding member 18 is sandwiched between the heat sink 10 and the PCB 20, and surrounding the CPU 22. Therefore, the heat sink 10 is capable of removing heat generated by the CPU 22 and shielding EMI generated by the CPU, as well.

Alternatively, the bottom of the main body 11 is flat, and a thickness of the shielding member 18 is greater than a thickness of the CPU 22.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A motherboard assembly comprising:
a printed circuit board (PCB) having an electronic component mounted thereto; and
a heat sink comprising:
a main body for removing heat from the electronic component; and
a shielding member mounted to a bottom of the main body, the shielding member defining an opening therein, for accommodating the electronic component, the shielding member sandwiched between the bottom of the main body and the PCB.

2. The motherboard assembly as claimed in claim 1, wherein a plurality of through-holes is defined in the PCB surrounding the electronic component, and a plurality of posts extend down from the main body in alignment with the through-holes respectively for mounting the heat sink to the PCB.

3. The motherboard assembly as claimed in claim 2, wherein each of the posts of the main body defines a screw hole in a bottom thereof, a fastener is engaged in the screw hole to secure the heat sink to the PCB.

4. The motherboard assembly as claimed in claim 1, wherein a recess is defined in a middle portion of the bottom of the main body for receiving the electronic component therein.

5. The motherboard assembly as claimed in claim 1, wherein a plurality of blind holes is defined in the main body.

6. The motherboard assembly as claimed in claim 5, wherein an array of the blind holes is in the form of a honeycomb.

7. The motherboard assembly as claimed in claim 6, wherein each of the blind holes has a maximum width of less than one-hundredth of a wavelength of electromagnetic waves generated by the electronic component.

8. The motherboard assembly as claimed in claim 1, wherein the shielding member is made of electric sponge.

9. A heat sink comprising:
a main body for removing heat from an electronic component; and
a shielding member mounted to a bottom of the main body and configured for shielding electromagnetic waves generated by the electronic component, the shielding member defining an opening therein, for accommodating the electronic component.

10. The heat sink as claimed in claim 9, wherein a recess is defined in a middle portion of the bottom of the main body for receiving the electronic component therein.

11. The heat sink as claimed in claim 9, wherein a plurality of blind holes is defined in the main body.

12. The heat sink as claimed in claim 11, wherein an array of the blind holes is in the form of a honeycomb.

13. The heat sink as claimed in claim 9, wherein the shielding member is made of electric sponge.

14. The heat sink as claimed in claim 9, wherein the shielding member is adhered to the bottom of the main body.

15. The heat sink as claimed in claim 9, wherein a plurality of posts extends down from the main body.

16. The heat sink as claimed in claim 15, wherein each of the posts defines a screw hole in a bottom thereof.

17. A heat sink comprising:
a main body defining a plurality of blind holes therein, each of the blind holes open at a top of the main body, and close at a bottom of the main body.

18. The heat sink as claimed in claim 17, wherein an array of the blind holes is in the form of a honeycomb.

19. The heat sink as claimed in claim 17, wherein a recess is defined in a middle portion of the bottom of the main body for receiving an electronic component therein.
